(19) United States
(12) Patent Application Publication
(10) Pub. No.: US 2023/0422408 A1
(43) Pub. Date: Dec. 28, 2023

(54) PRINTED WIRING BOARD

(71) Applicant: IBIDEN CO., LTD., Ogaki (JP)

(72) Inventors: Jun SAKAI, Ogaki (JP); Kyohei YOSHIKAWA, Ogaki (JP)

(73) Assignee: IBIDEN CO., LTD., Ogaki (JP)

(21) Appl. No.: 18/338,661

(22) Filed: Jun. 21, 2023

(30) Foreign Application Priority Data
Jun. 22, 2022 (JP) 2022-100320

(51) Int. Cl. H05K 3/42; H05K 3/18

(52) U.S. Cl. CPC H05K 3/423; H05K 3/429; H05K 3/188

(57) ABSTRACT

A printed wiring board includes a first conductor layer, a resin insulating layer having an opening extending from a first surface to a second surface of the resin insulating layer and laminated on the first conductor layer, a second conductor layer formed on the first surface of the resin insulating layer such that the first conductor layer is facing the second surface of the resin insulating layer on the opposite side with respect to the first surface, and a via conductor formed in the opening of the resin insulating layer such that the via conductor is connecting the first conductor layer and the second conductor layer and that the via conductor and the second conductor layer include a seed layer and an electrolytic plating layer formed on the seed layer. The seed layer includes an amorphous metal in a range of 5 wt % to 80 wt %.

### CROSS-REFERENCE TO RELATED APPLICATIONS

The present application is based upon and claims the benefit of priority to Japanese Patent Application No. 2022-100320, filed Jun. 22, 2022, the entire contents of which are incorporated herein by reference.

### BACKGROUND OF THE INVENTION

### Field of the Invention

A technology disclosed herein relates to a printed wiring board.

### Description of Background Art

Japanese Patent Application Laid-Open Publication No. H11-214828 describes a printed wiring board in which a conductor circuit is formed on an insulating layer having a roughened surface. The entire contents of this publication are incorporated herein by reference.

### SUMMARY OF THE INVENTION

According to one aspect of the present invention, a printed wiring board includes a first conductor layer, a resin insulating layer having an opening extending from a first surface to a second surface of the resin insulating layer and laminated on the first conductor layer, a second conductor layer formed on the first surface of the resin insulating layer such that the first conductor layer is facing the second surface of the resin insulating layer on the opposite side with respect to the first surface, and a via conductor formed in the opening of the resin insulating layer such that the via conductor is connecting the first conductor layer and the second conductor layer and that the via conductor and the second conductor layer include a seed layer and an electrolytic plating layer formed on the seed layer. The seed layer includes an amorphous metal in a range of 5 wt % to 80 wt %.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a printed wiring board according to an embodiment of the present invention;

FIG. 2A is a cross-sectional view schematically illustrating a method for manufacturing a printed wiring board according to an embodiment of the present invention;

FIG. 2B is a cross-sectional view schematically illustrating a method for manufacturing a printed wiring board according to an embodiment of the present invention;

FIG. 2C is a cross-sectional view schematically illustrating a method for manufacturing a printed wiring board according to an embodiment of the present invention;

FIG. 2D is a cross-sectional view schematically illustrating a method for manufacturing a printed wiring board according to an embodiment of the present invention;

FIG. 2E is a cross-sectional view schematically illustrating a method for manufacturing a printed wiring board according to an embodiment of the present invention;

FIG. 2F is a cross-sectional view schematically illustrating a method for manufacturing a printed wiring board according to an embodiment of the present invention;

FIG. 2G is a cross-sectional view schematically illustrating a method for manufacturing a printed wiring board according to an embodiment of the present invention; and

FIG. 3 is a cross-sectional view schematically illustrating a printed wiring board of a modified embodiment of the embodiment.

### DETAILED DESCRIPTION OF THE EMBODIMENTS

Embodiments will now be described with reference to the accompanying drawings, wherein like reference numerals designate corresponding or identical elements throughout the various drawings.

### Embodiment

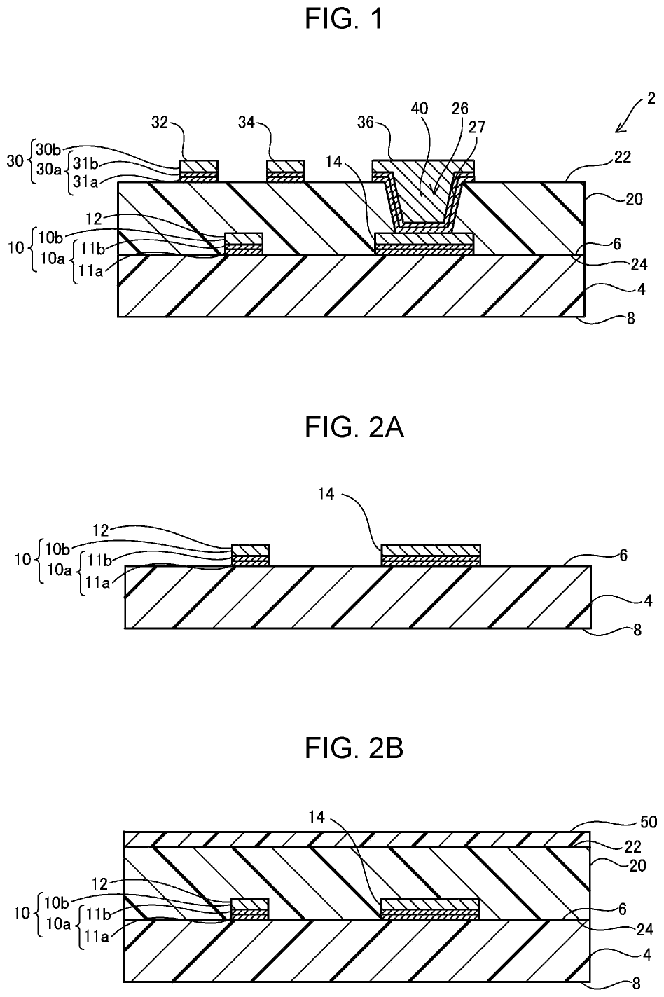

FIG. 1 is a cross-sectional view illustrating a printed wiring board 2 of an embodiment. As illustrated in FIG. 1, the printed wiring board 2 includes an insulating layer 4, a first conductor layer 10, a resin insulating layer 20, a second conductor layer 30, and a via conductor 40.

The insulating layer 4 is formed using a resin. The insulating layer 4 may contain inorganic particles such as silica particles or alumina particles. The insulating layer 4 may contain a reinforcing material such as a glass cloth. The insulating layer 4 has a third surface 6 (upper surface in the drawing) and a fourth surface 8 (lower surface in the drawing) on the opposite side with respect to the third surface 6.

The first conductor layer 10 is formed on the third surface 6 of the insulating layer 4. The first conductor layer 10 includes a signal wiring 12 and a pad 14. Although not illustrated in the drawing, the first conductor layer 10 also includes conductor circuits other than the signal wiring 12 and the pad 14. The first conductor layer 10 is mainly formed of copper. The first conductor layer 10 is formed of a seed layer (10a) on the insulating layer 4 and an electrolytic plating layer (10b) on the seed layer (10a). The seed layer (10a) is formed by a first layer (11a) on the third surface 6 and a second layer (11b) on the first layer (11a). Both the first layer (11a) and the second layer (11b) are sputtering films formed by sputtering. The first layer (11a) has a thickness of 10 nm or more and 500 nm or less. The second layer (11b) has a thickness of 10 nm or more and 1,000 nm or less. The seed layer (10a) contains 5 wt % or more and 80 wt % or less of an amorphous metal. That is, both the first layer (11a) and the second layer (11b) contain 5 wt % or more and 80 wt % or less of an amorphous metal. The first layer (11a) is formed of a copper alloy containing copper, silicon and aluminum. The copper content in the copper alloy is 90 at % or more and less than 99 at %. The copper content in the copper alloy is 90 at % or more and 98 at % or less. The second layer (11b) is formed of copper. The copper content in the second layer (11b) is 99 at % or more. The electrolytic plating layer (10b) is formed of copper. The first layer (11a) is in contact with the insulating layer 4.

A device for measuring the crystallinity of the seed layer (10a) is, for example, SEM “S-4300SE” manufactured by Hitachi High-Tech, EBSD “PEGAPUS Integration System” manufactured by TSL Solutions, or the like. Analysis conditions are, for example, an acceleration voltage of 15 kV and a measurement area of (6 μm)×(15 μm) (step size: 0.05 μm). Data processing conditions are, for example, a minimum grain size of 5 points, a grain boundary definition angle of 5 degrees or more, and a GCI of greater than 0.1.

The resin insulating layer 20 is formed on the third surface 6 of the insulating layer 4 and on the first conductor layer 10. The resin insulating layer 20 has a first surface 22 (upper surface in the drawing) and a second surface 24 (lower surface in the drawing) on the opposite side with respect to the first surface 22. The second surface 24 of the resin insulating layer 20 faces the first conductor layer 10. The resin insulating layer 20 has an opening 26 that expose the pad 14. The resin insulating layer 20 is formed of an epoxy resin and inorganic particles dispersed in the epoxy resin. Examples of the resin include a thermosetting resin and a photocurable resin. Examples of the inorganic particles include silica particles and alumina particles. An amount of the inorganic particles in the resin insulating layer 20 is 75 wt % or more.

The first surface 22 of the resin insulating layer 20 is formed mostly of the resin. Some of the inorganic particles are exposed in a small amount from the first surface 22. No unevenness is formed on the first surface 22 of the resin insulating layer 20. The first surface 22 is not roughened. The first surface 22 is formed substantially smooth. The first surface 22 has an arithmetic mean roughness (Ra) of 0.02 μm or more and 0.08 μm or less.

The second conductor layer 30 is formed on the first surface 22 of the resin insulating layer 20. The second conductor layer 30 includes a first signal wiring 32, a second signal wiring 34, and a land 36. Although not illustrated in the drawing, the second conductor layer 30 also includes conductor circuits other than the first signal wiring 32, the second signal wiring 34, and the land 36. The first signal wiring 32 and the second signal wiring 34 form a pair wiring. The first signal wiring 32 and the second signal wiring 34 are adjacent to each other.

The second conductor layer 30 is mainly formed of copper. The second conductor layer 30 is formed by a seed layer (30a) on the first surface 22 and an electrolytic plating layer (30b) on the seed layer (30a). The seed layer (30a) is formed by a first layer (31a) on the first surface 22 and a second layer (31b) on the first layer (31a). Both the first layer (31a) and the second layer (31b) are sputtering films formed by sputtering. The first layer (31a) has a thickness of 10 nm or more and 500 nm or less. The second layer (31b) has a thickness of 10 nm or more and 1,000 nm or less. The seed layer (30a) contains 5 wt % or more and 80 wt % or less of an amorphous metal. That is, both the first layer (31a) and the second layer (31b) contain 5 wt % or more and 80 wt % or less of an amorphous metal. The first layer (31a) is formed of a copper alloy containing copper, silicon and aluminum. The content of copper in the copper alloy is 90 at % or more and less than 99 at %. The copper content in the copper alloy is 90 at % or more and 98 at % or less. The second layer (31b) is formed of copper. The copper content in the second layer (31b) is 99 at % or more. The electrolytic plating layer (30b) is formed of copper. The first layer (31a) is in contact with the first surface 22.

The crystallinity measuring device, analysis conditions, and data processing conditions for the seed layer (30a) are the same as above.

The via conductor 40 is formed in the opening 26. The via conductor 40 connects the first conductor layer 10 and the second conductor layer 30. In FIG. 1, the via conductor 40 connects the pad 14 and the land 36. The via conductor 40 is formed of a seed layer (30a) and an electrolytic plating layer (30b) on the seed layer (30a). The seed layer (30a) forming the via conductor 40 and the seed layer (30a) forming the second conductor layer are the same. The seed layer (30a) forming the via conductor 40 is formed of a first layer (31a) covering inside (that is, the inner wall surface 27 of the opening 26 and the upper surface of the pad 14 exposed from the opening 26) of the opening 26 and a second layer (31b) on the first layer (31a). The first layer (31a) is in contact with the upper surface of the pad 14 and the inner wall surface 27.

Although not illustrated in the drawings, each side of the printed wiring board 2 has a length of 50 mm or more. The length of each side is preferably 100 mm or more. The length of each side is 250 mm or less.

### Method for Manufacturing Printed Wiring Board

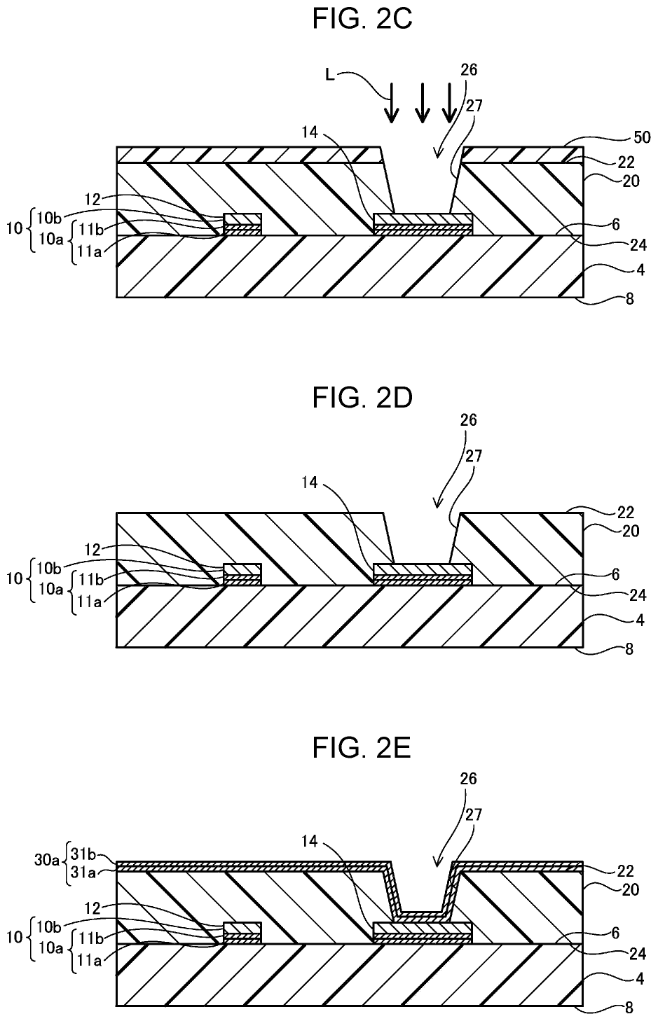

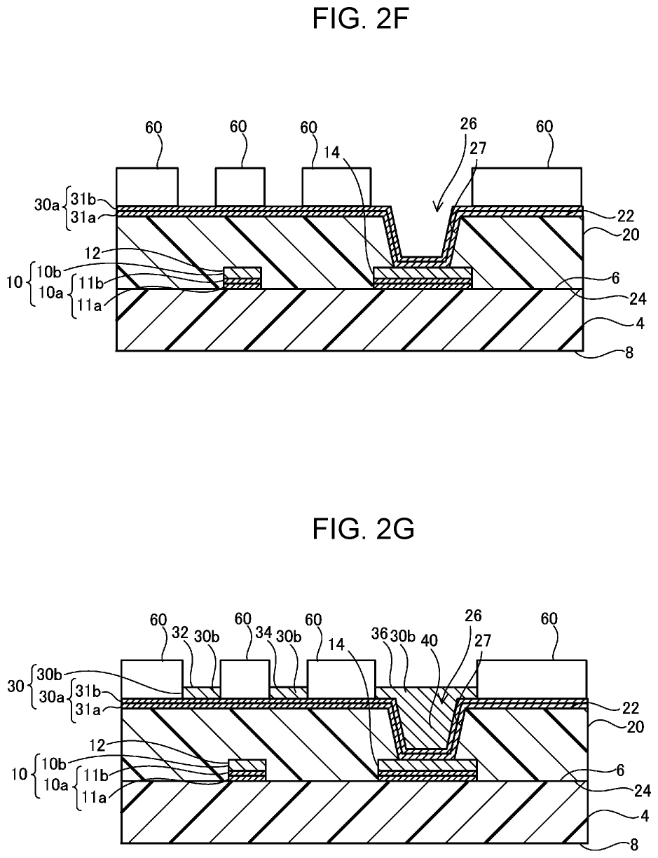

FIGS. 2A-2G illustrate a method for manufacturing the printed wiring board 2 of the embodiment. FIGS. 2A-2G are cross-sectional views. FIG. 2A illustrates the insulating layer 4 and the first conductor layer 10 formed on the third surface 6 of the insulating layer 4. The first conductor layer 10 is formed using a semi-additive method. The first layer (11a) and second layer (11b) are formed by sputtering. The electrolytic plating layer (10b) is formed by electrolytic plating.

As illustrated in FIG. 2B, the resin insulating layer 20 and a protective film 50 are formed on the insulating layer 4 and the first conductor layer 10. The second surface 24 of the resin insulating layer 20 faces the third surface 6 of the insulating layer 4. The protective film 50 is formed on the first surface 22 of the resin insulating layer 20.

The protective film 50 completely covers the first surface 22 of the resin insulating layer 20. An example of the protective film 50 is a film formed of polyethylene terephthalate (PET). A release agent is formed between the protective film 50 and the resin insulating layer 20.

As illustrated in FIG. 2C, laser (L) is irradiated from above the protective film 50. The laser (L) penetrates the protective film 50 and the resin insulating layer 20 at the same time. The opening 26 for a via conductor reaching the pad 14 of the first conductor layer 10 is formed. The laser (L) is, for example, UV laser, or CO2 laser. The pad 14 is exposed from the opening 26. When the opening 26 is formed, the first surface 22 is covered by the protective film 50. Therefore, when the opening 26 is formed, even when the resin scatters, adherence of the resin to the first surface 22 is suppressed.

After that, the inside of the opening 26 is cleaned. Resin residues generated when the opening 26 is formed are removed. The cleaning of the inside of the opening 26 is performed using plasma. That is, the cleaning is performed in a dry process. The cleaning includes a desmear treatment. The inner wall surface 27 of the opening 26 is roughened with plasma. The inner wall surface 27 of the opening 26 is formed of the resin and the inorganic particles that form the resin insulating layer 20. On the other hand, the first surface 22 of the resin insulating layer 20 is covered by the protective film 50. The first surface 22 is not affected by the plasma. No unevenness is formed on the first surface 22 of the resin insulating layer 20. The first surface 22 is not roughened. Some of the inorganic particles are exposed in a small amount on the first surface 22. The first surface 22 is formed substantially smooth.

As illustrated in FIG. 2D, the protective film 50 is removed from the resin insulating layer 20. After the protective film 50 is removed, the first surface 22 is dry etched. The dry etching is performed by sputtering using argon gas (argon sputtering). Due to the dry etching, the inorganic particles are slightly exposed on the first surface 22. Roughening of the first surface 22 of the first resin insulating layer 20 is not performed.

As illustrated in FIG. 2E, the seed layer (30a) is formed on the first surface 22 of the resin insulating layer 20. The seed layer (30a) is formed by sputtering. The formation of the seed layer (30a) is performed in a dry process. The first layer (31a) is formed on the first surface 22. At the same time, the first layer (31a) is formed on the inner wall surface 27 and the pad 14, which are exposed from the opening 26. After that, the second layer (31b) is formed on the first layer (31a). The first layer (31a) is formed of a copper alloy containing copper, silicon and aluminum. The second layer (31b) is formed of copper.

When the first layer (31a) and the second layer (31b) are formed by sputtering, sputtering conditions are adjusted such that a distance between a target and a substrate surface in a sputtering device is in a range of 50 mm or more and 250 mm or less, a voltage is in a range of 15 eV or more and 50 eV or less, and a gas concentration is in a range of 0.1 Pa or more and 1.0 Pa or less. As a result, the first layer (31a) is formed to have a thickness of 10 nm or more and 500 nm or less. The second layer (31b) is formed to have a thickness of 10 nm or more and 1,000 nm or less. Both the first layer (31a) and the second layer (31b) contain 5 wt % or more and 80 wt % or less of an amorphous metal.

As illustrated in FIG. 2F, a plating resist 60 is formed on the seed layer (30a). The plating resist 60 has openings for forming the first signal wiring 32, the second signal wiring 34, and the land 36 (FIG. 1).

As illustrated in FIG. 2G, the electrolytic plating layer (30b) is formed on the seed layer (30a) exposed from the plating resist 60. The electrolytic plating layer (30b) is formed of copper. The electrolytic plating layer (30b) fills the opening 26. The first signal wiring 32, the second signal wiring 34, and the land 36 are formed by the seed layer (30a) and the electrolytic plating film (30b) on the first surface 22. The second conductor layer 30 is formed. The via conductor 40 is formed by the seed layer (30a) and the electrolytic plating film (30b) in the opening 26. The via conductor 40 connects the pad 14 and the land 36. The first signal wiring 32 and the second signal wiring 34 form a pair wiring.

After that, the plating resist 60 is removed. The seed layer (30a) exposed from the electrolytic plating layer (30b) is removed. The seed layer (30a) is removed by wet etching. By the wet etching, the first layer (31a) and the second layer (31b) are removed at the same time. The second conductor layer 30 and the via conductor 40 are formed at the same time. The printed wiring board 2 (FIG. 1) of the embodiment is obtained.

In the printed wiring board 2 of the embodiment (FIG. 1), the seed layer (30a) (the first layer (31a) and the second layer (31b)) contains 5 wt % or more and 80 wt % or less of an amorphous metal. The seed layer (30a) containing 5 wt % or more and 80 wt % or less of an amorphous metal is more easily removed by wet etching than a seed layer that does not contain an amorphous metal. When the seed layer (30a) is removed in a manufacturing process of the printed wiring board 2, an etching amount is reduced. Since the electrolytic plating layer (30b) is not excessively removed, the second conductor layer 30 having the first signal wiring 32 and the second signal wiring 34 has widths as designed. Fine wirings are formed. Further, since surfaces of the first signal wiring 32 and the second signal wiring 34 in the second conductor layer 30 are unlikely to be roughened, transmission loss is reduced. As a result, a high-quality printed wiring board 2 is provided.

### First Alternative Example of Embodiment

In a first alternative example of the embodiment, the first layers (11a, 31a) of the seed layers (10a, 30a) are each formed of copper and a second element. The second element is selected from silicon, aluminum, titanium, nickel, chromium, carbon, oxygen, tin, calcium, magnesium, iron, molybdenum, and silver. The first layers (11a, 31a) are each formed of an alloy containing copper. The second layers (11b, 31b) are each formed of copper. The copper content (at %) forming the second layers (11b, 31b) is 99.9 at % or more, and preferably 99.95 at % or more.

### Second Alternative Example of Embodiment

In a second alternative example of the embodiment, the first layers (11a, 31a) of the seed layers (10a, 30a) are each formed of any one metal of aluminum, titanium, nickel, chromium, calcium, magnesium, iron, molybdenum, and silver.

### Third Alternative Example of Embodiment

In a third alternative example of the embodiment, the seed layer (10a) is formed by electroless plating.

### Modified Embodiment of Embodiment

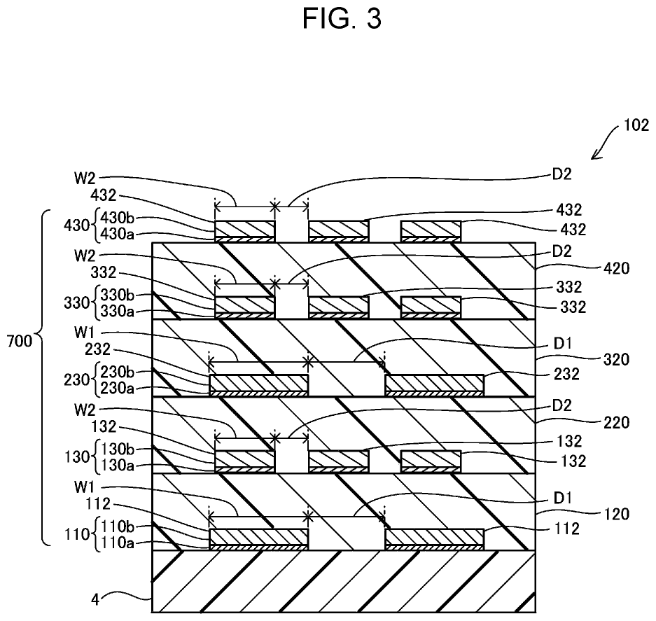

FIG. 3 illustrates a modified embodiment of the embodiment. As illustrated in FIG. 3, a printed wiring board 102 of the modified embodiment has a build-up layer 700 on the insulating layer 4. The buildup layer 700 includes multiple conductor layers and multiple resin insulating layers. The conductor layers and the resin insulating layers are alternately laminated. The build-up layer 700 includes five conductor layers and four resin insulating layers.

The five conductor layers include a first conductor layer 110, a second conductor layer 130, a third conductor layer 230, a fourth conductor layer 330, and a fifth conductor layer 430. The conductor layers are each formed of a seed layer (110a, 130a, 230a, 330a, 430a) and an electrolytic plating layer (110b, 130b, 230b, 330b, 430b).

The seed layer (110a) of the first conductor layer 110 and the seed layer (230a) of the third conductor layer 230 are electroless plating films formed by electroless plating. The seed layers (110a, 230a) do not contain an amorphous metal. Hereinafter, the seed layers (110a, 230a) may be referred to as “first type seed layers.” The electrolytic plating layers (110b, 230b) on the first type seed layers (seed layers (110a, 230a)) may be referred to as “first type electrolytic plating layers.” The first conductor layer 110 and the third conductor layer 230 may be referred to as “first type conductor layers.” The first type conductor layers are each, for example, a signal wiring layer including a signal wiring.

On the other hand, the second conductor layer 130, the fourth conductor layer 330, and the fifth conductor layer 430 are similar to the second conductor layer 30 of the embodiment. That is, the seed layer (130a) of the second conductor layer 130, the seed layer (330a) of the fourth conductor layer 330, and the seed layer (430a) of the fifth conductor layer 430 are sputtering films formed by sputtering. Although not illustrated in FIG. 3, the seed layers (130a, 330a, 430a) each have a first layer formed of a copper alloy and a second layer formed of copper. The seed layers (130a, 330a, 430a) contain 5 wt % or more and 80 wt % or less of an amorphous metal. Hereinafter, the seed layers (130a, 330a, 430a) may be referred to as “second type seed layers.” The electrolytic plating layers (130b, 330b, 430b) on the second seed layers (seed layers (130a, 330a, 430a)) may be referred to as “second type electrolytic plating layers.” The second conductor layer 130, the fourth conductor layer 330, and the fifth conductor layer 430 may be referred to as “second type conductor layers.” The second type conductor layers are each, for example, a power supply layer or a ground layer.

The four resin insulating layers include a first resin insulating layer 120, a second resin insulating layer 220, a third resin insulating layer 320, and a fourth resin insulating layer 420. The first resin insulating layer 120 is similar to the resin insulating layer 20 of the embodiment. The second resin insulating layer 220, the third resin insulating layer 320, and the fourth resin insulating layer 420 have the same structure (the resin and the inorganic particles) as the first resin insulating layer 120. The first resin insulating layer 120, the second resin insulating layer 220, the third resin insulating layer 320, and the fourth resin insulating layer 420 are formed using the same method as that for the resin insulating layer 20 of the embodiment.

Although not illustrated, the first resin insulating layer 120, the second resin insulating layer 220, the third resin insulating layer 320, and the fourth resin insulating layer 420 have openings. Via conductors are formed in the openings. The via conductors in the openings of the first resin insulating layer 120 connect the first conductor layer 110 and the second conductor layer 130. The via conductors in the openings of the second resin insulating layer 220 connect the second conductor layer 130 and the third conductor layer 230. The via conductors in the openings of the third resin insulating layer 320 connect the third conductor layer 230 and the fourth conductor layer 330. The via conductors in the openings of the fourth resin insulating layer 420 connect the fourth conductor layer 330 and the fifth conductor layer 430.

As illustrated in FIG. 3, the first type conductor layers (the first conductor layer 110 and the third conductor layer 230) have multiple first conductor circuits (112, 232). The second type conductor layers (the second conductor layer 130, the fourth conductor layer 330, and the fifth conductor layer 430) have multiple second conductor circuits (132, 332, 432). A width (W2) of each of the second conductor circuits 132 (332, 432) is smaller than a width (W1) of each of the first conductor circuits 112 (232). The width (W2) is 2 μm or more and 8 μm or less. The width (W1) is 8 μm or more and 12 μm or less. Further, a distance (D2) between two adjacent second conductor circuits 132 (332, 432) is smaller than a distance (D1) between two adjacent first conductor circuits 112 (232). The distance (D2) is 3 μm or more and 10 μm or less. The distance (D1) is 9 μm or more and 13 μm or less. The width (W1) and the width (W2) are respectively examples of a “first width” and a “second width.” The distance (D1) and the distance (D2) are respectively examples of a “first distance” and a “second distance.”

### Alternative Example of Modified Embodiment

The build-up layer 700 has 5 or more conductor layers. The build-up layer 700 preferably has 10 or more conductor layers. The number of the conductor layers is 20 or less.

Japanese Patent Application Laid-Open Publication No. H11-214828 describes a printed wiring board in which a conductor circuit is formed on an insulating layer having a roughened surface. The conductor circuit is formed of an electroless plating film formed on the insulating layer and an electrolytic plating film formed on the electroless plating film. The electroless plating film is formed following the roughened surface of the insulating layer.

In Japanese Patent Application Laid-Open Publication No. H11-214828, the electroless plating film is formed following the roughened surface of the insulating layer. A part of the electroless plating film is formed entering an inner side of the surface of the insulating layer. It is thought that when the electroless plating film is removed in a manufacturing process, an etching amount is large. It is thought that the electrolytic plating film is excessively removed. Therefore, it is thought that it is difficult to form a fine wiring. Further, it is thought that, since the surface of the conductor circuit is roughened, transmission loss increases. As a result, it is thought that a high-quality printed wiring board is not provided.

A printed wiring board according to an embodiment of the present invention includes: a first conductor layer; a resin insulating layer that has a first surface and a second surface on the opposite side with respect to the first surface, an opening extending from the first surface to the second surface, and is laminated on the first conductor layer such that the second surface faces the first conductor layer; a second conductor layer that is formed on the first surface of the resin insulating layer; and a via conductor that is formed in the opening and connects the first conductor layer and the second conductor layer. The second conductor layer and the via conductor are formed of a seed layer and an electrolytic plating layer formed on the seed layer. The seed layer contains 5 wt % or more and 80 wt % or less of an amorphous metal.

In a printed wiring board according to an embodiment of the present invention, the seed layer contains 5 wt % or more and 80 wt % or less of an amorphous metal. The seed layer containing 5 wt % or more and 80 wt % or less of an amorphous metal is more easily removed by etching than a seed layer that does not contain an amorphous metal. When the seed layer is removed in a manufacturing process of the printed wiring board, an etching amount is reduced. Since the electrolytic plating layer is not excessively removed, a fine wiring is formed. Further, since the surface of the conductor circuit in the second conductor layer is unlikely to be roughened, transmission loss is reduced. As a result, a high-quality printed wiring board is provided.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a first conductor layer;
a resin insulating layer having an opening extending from a first surface to a second surface of the resin insulating layer and laminated on the first conductor layer;
a second conductor layer formed on the first surface of the resin insulating layer such that the first conductor layer is facing the second surface of the resin insulating layer on an opposite side with respect to the first surface; and
a via conductor formed in the opening of the resin insulating layer such that the via conductor is connecting the first conductor layer and the second conductor layer and that the via conductor and the second conductor layer include a seed layer and an electrolytic plating layer formed on the seed layer,
wherein the seed layer includes an amorphous metal in a range of 5 wt % to 80 wt %.

2. The printed wiring board according to claim 1, wherein the seed layer is a sputtering film.

3. The printed wiring board according to claim 1, wherein the seed layer has a first layer and a second layer formed on the first layer such that a material of the second layer is different from a material of the first layer.

4. The printed wiring board according to claim 3, wherein the seed layer is formed such that the first layer has a thickness in a range of 10 nm to 500 nm and that the second layer has a thickness in a range of 10 nm to 1,000.

5. The printed wiring board according to claim 1, wherein the resin insulating layer is formed such that the first surface has an arithmetic mean roughness Ra in a range of 0.02 μm to 0.08 μm.

6. The printed wiring board according to claim 3, wherein the seed layer is formed such that the material of the first layer is a copper alloy and that the material of the second layer is a copper alloy that is different from the copper alloy of the first layer.

7. The printed wiring board according to claim 6, wherein the copper alloy of the first layer has a copper content of 90 wt % or more, and the copper alloy of the second layer has a copper content of 90 wt % or more.

8. The printed wiring board according to claim 6, wherein the copper alloy of the first layer includes at least one element selected from the group consisting of silicon, aluminum, titanium, nickel, chromium, iron, molybdenum, silver, carbon, oxygen, tin, calcium and magnesium, and the copper alloy of the second layer includes at least one element selected from the group consisting of silicon, aluminum, titanium, nickel, chromium, iron, molybdenum, silver, carbon, oxygen, tin, calcium and magnesium.

9. The printed wiring board according to claim 3, wherein the material of the first layer is a copper alloy including aluminum and silicon, and the material of the second layer is copper.

10. The printed wiring board according to claim 3, wherein the material of the first layer includes at least one element selected from the group consisting of aluminum, titanium, nickel, chromium, calcium, magnesium, iron, molybdenum and silver, and the material of the second layer is copper.

11. The printed wiring board according to claim 1, further comprising:
a plurality of insulating layers; and
a plurality of conductor layers comprising a plurality of first type conductor layers and a plurality of second type conductor layers,
wherein each of the first type conductor layers includes a first type seed layer not containing an amorphous metal, and a first type electrolytic plating layer formed on the first type seed layer, each of the second type conductor layers includes a second type seed layer comprising an amorphous metal in a range of 5 wt % to 80 wt %, and a second type electrolytic plating layer formed on the second type seed layer, the second conductor layer includes the second type seed layer and the second type electrolytic plating layer formed on the second type seed layer, and the first conductor layer, the second conductor layer, the resin insulating layer, the plurality of insulating layers and the plurality of conductor layers form a build-up layer.

12. The printed wiring board according to claim 11, wherein the first type seed layer is an electroless plating film, and the second type seed layer is a sputtering film.

13. The printed wiring board according to claim 11, wherein each of the first type conductor layers includes a plurality of first conductor circuits, and each of the second type conductor layers includes a plurality of second conductor circuits such that each of the second conductor circuits has a second width that is smaller than a first width of each of the first conductor circuits and that a second distance between two adjacent second conductor circuits is smaller than a first distance between two adjacent first conductor circuits.

14. The printed wiring board according to claim 13, wherein the first and second type conductor layers are formed such that the first width is in a range of 8 μm to 12 μm, the second width is in a range of 2 μm to 8 μm, the first distance is in a range of 9 μm to 13 μm, and the second distance is in a range of 3 μm to 10 μm.

15. The printed wiring board according to claim 3, wherein the seed layer is formed such that the material of the first layer is a copper alloy and that the material of the second layer is copper.

16. The printed wiring board according to claim 15, wherein the copper alloy of the first layer has a copper content of 90 wt % or more.

17. The printed wiring board according to claim 15, wherein the copper alloy of the first layer includes at least one element selected from the group consisting of silicon, aluminum, titanium, nickel, chromium, iron, molybdenum, silver, carbon, oxygen, tin, calcium and magnesium.

18. The printed wiring board according to claim 2, wherein the seed layer has a first layer and a second layer formed on the first layer such that a material of the second layer is different from a material of the first layer.

19. The printed wiring board according to claim 18, wherein the seed layer is formed such that the first layer has a thickness in a range of 10 nm to 500 nm and that the second layer has a thickness in a range of 10 nm to 1,000.

20. The printed wiring board according to claim 2, wherein the resin insulating layer is formed such that the first surface has an arithmetic mean roughness Ra in a range of 0.02 μm to 0.08 μm.
